(19) United States
(12) Patent Application Publication
(10) Pub. No.: US 2010/0108972 A1
(43) Pub. Date: May 6, 2010

(54) NON-VOLATILE SEMICONDUCTOR MEMORY DEVICES

(75) Inventors: Jinshi Zhao, Hwaseong-si (KR); Hyung-Ik Lee, Suwon-si (KR); Seong-Ho Moon, Suwon-si (KR); In-Gyu Baek, Seoul (KR); Hyun-Jun Sim, Hwaseong-si (KR); Eun-Kyung Yim, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/611,135

(22) Filed: Nov. 3, 2009

(30) Foreign Application Priority Data
Nov. 4, 2008 (KR) 10-2008-0108823

(51) Int. Cl. H01L 47/00

(52) U.S. Cl. 257/2; 257/E47.001; 257/43

(57) ABSTRACT

A non-volatile semiconductor memory device includes a lower electrode, an upper electrode, a resistive layer pattern between the lower electrode and the upper electrode, and a filament seed embedded in the resistive layer pattern. The filament seed includes at least one of a carbon nanotube, a nanowire and a nanoparticle.

### CROSS-REFERENCE TO RELATED APPLICATION

A claim of priority under 35 U.S.C. §119 is made to Korean patent Application No. 10-2008-0108823, filed Nov. 4, 2008, the disclosure of which is hereby incorporated by reference herein in its entirety.

### BACKGROUND

Example embodiments relate to non-volatile semiconductor memory devices and to methods of manufacturing non-volatile semiconductor memory devices.

Non-volatile semiconductor memory devices retain stored data in the absence of supplied power. Examples of the non-volatile memory devices include ferroelectric random access memory (FRAM) devices, magnetic random access memory (MRAM) devices, resistive random access memory (RRAM) devices and phase-change random access memory (PRAM) devices. Among these examples, the RRAM device is characterized by varying a cell resistance according to an applied voltage and by a cell structure in which a resistive layer is disposed between a lower electrode and an upper electrode. The resistance value of the resistive layer may be programmed to at least a reset state or a set state by application of an applied voltage(s) or current pulse(s).

### SUMMARY

According to some example embodiments, a non-volatile semiconductor memory device is provided. The non-volatile semiconductor memory device includes a lower electrode, an upper electrode, a resistive layer pattern located between the lower electrode and the upper electrode, and a filament seed embedded in the resistive layer pattern, where the filament seed includes at least one of a carbon nanotube, a nanowire and a nanoparticle.

According to example embodiments, there is provided a method of manufacturing a non-volatile semiconductor memory device. The method includes forming a lower electrode on a substrate, forming a filament seed on the lower electrode, forming a resistive layer pattern to cover the filament seed, and forming an upper electrode on the resistive layer pattern. The filament seed includes at least one of a carbon nanotube, a nanowire and a nanoparticle.

According to some example embodiments, a non-volatile semiconductor memory device is provided. The non-volatile semiconductor memory device includes a switching element on a substrate, a first electrode electrically connected to the switching element, a resistive layer pattern surrounding the first electrode such that an inner sidewall of the resistive layer pattern confronts the first electrode, a second electrode which contacts an outer a sidewall of the resistive layer pattern, and filament seeds including at least one of a carbon nanotube, a nanowire and a nanoparticle embedded in the resistive layer pattern.

### BRIEF DESCRIPTION OF THE DRAWINGS

Example embodiments will be more clearly understood from the following detailed description taken in conjunction with the accompanying drawings. FIGS. 1 to 16 represent non-limiting, example embodiments as described herein.

FIG. 1 is a cross sectional view illustrating a non-volatile semiconductor memory device in accordance with example embodiments.

FIG. 2 is a conceptional view illustrating a filament randomly formed on an interfacial layer.

FIG. 3 is a graph illustrating a current value relative to applied voltages when the voltage is applied to a conventional non-volatile semiconductor memory device.

FIGS. 4 to 7 are cross sectional views illustrating a method of manufacturing a non-volatile semiconductor memory device in accordance with example embodiments.

FIG. 8 is a cross sectional view illustrating a non-volatile semiconductor memory device in accordance with example embodiments.

FIGS. 9 to 12 are cross sectional views illustrating a method of manufacturing a non-volatile semiconductor memory device in accordance with example embodiments.

FIG. 13 is a cross sectional view illustrating a non-volatile semiconductor memory device in accordance with example embodiments.

FIGS. 14 to 16 are block diagrams illustrating a system including a non-volatile semiconductor memory device in accordance with example embodiments.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third and so on. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross sectional view illustrating a non-volatile semiconductor memory device in accordance with example embodiments.

Referring to FIG. 1, a non-volatile semiconductor memory device 180 includes a substrate 100, a switching element 110, an insulating interlayer pattern 115, a lower electrode 120, an insulation layer pattern 130, a filament seed 140, a resistive layer pattern 150, a spacer 170 and an upper electrode 160.

The substrate 100 may include a semiconductor substrate such as silicon substrate, a germanium substrate, a silicon-germanium substrate, a silicon-on-insulator (SOI) substrate, a germanium-on-insulator (GOI) substrate, and so on. Alternatively, the substrate may include a single crystalline metal oxide substrate. For example, the substrate may include a single crystalline aluminum oxide (Al₂O₃) substrate, a single crystalline strontium titanium oxide (SrTiO₃) substrate or a single crystalline magnesium oxide (MgO) substrate.

The insulating interlayer pattern 115 is formed on the substrate 100. The insulating interlayer pattern 115 may include an opening. In example embodiments, the insulating interlayer pattern 115 may include boro-phosphor silicate glass (BPSG), phosphor silicate glass (PSG), undoped silicate glass (USG), spin on glass (SOG), flowable oxide (FOX), tetraethylorthosilicate (TEOS), plasma enhanced tetraethylorthosilicate (PE-TEOS), high density plasma chemical vapor deposition (HDP-CVD) oxide, and so on.

The switching element 110 is positioned in the opening of the insulating interlayer pattern 115. The switching element 110 may include a diode or a transistor such as a metal oxide semiconductor field effect transistor (MOSFET) formed on the substrate 100. In example embodiments, the transistor may include a gate structure and source/drain regions. In example embodiments, the diode may include a first polysilicon layer pattern doped with p-type impurities and a second polysilicon layer pattern doped with n-type impurities. Alternatively, the diode may include a Schottky diode having a polysilicon layer pattern doped with p-type impurities or a polysilicon layer pattern doped with n-type impurities.

A lower electrode 120 may be electrically connected to the switching element 110. The lower electrode 120 may include a metal or a metal compound having a high conductivity. In example embodiments, the lower electrode may include tungsten (W), aluminum (Al), titanium (Ti), hafnium (Hf), iron (Fe), cobalt (Co), zinc (Zn), manganese (Mn), molybdenum (Mo), niobium (Nb), copper (Cu) or a nitride thereof. The lower electrode 120 may include iridium (Ir), rubidium (Rb), platinum (Pt) or palladium (Pd). These may be used alone or in a combination thereof. For examples, the lower electrode 120 may be formed using iridium, rubidium, platinum or palladium to improve electrical characteristics of the non-volatile semiconductor memory device.

The non-volatile semiconductor memory device may include a catalyst layer (not illustrated) on the lower electrode 120. The catalyst layer may accelerate a growth of the filament seed 140. The catalyst layer may include a metal layer or a porous active layer. In example embodiments, the catalyst layer may include a tungsten, nickel (Ni), iron, cobalt, lead (Pb), platinum, cobalt silicide, nickel silicide, titanium silicide, or titanium tungsten. These may be used alone or in a combination of two or more thereof. The catalyst layer may have a thickness of about several nanometers to about several tens of nanometers.

The insulation layer pattern 130 is disposed between the lower electrode 120 and the upper electrode 160. The insulation layer pattern 130 may have an opening exposing a surface of the lower electrode 120. The opening may define a region on which the resistive layer pattern 150 is formed. When the opening has a narrow width, a contact area between the resistive layer pattern 130 and the lower electrode 120 may be decreased to improve electrical characteristics of the non-volatile semiconductor memory device 180. In example embodiments, the spacer 170 may be formed on a sidewall of the opening.

In example embodiments, the insulation layer pattern 130 may include silicon oxide. For example, the insulation layer pattern 150 may include boro-phosphor silicate glass, phosphor silicate glass, undoped silicate glass, spin on glass, flowable oxide, tetraethylorthosilicate, plasma enhanced tetraethylorthosilicate, high density plasma chemical vapor deposition oxide, and so on.

The filament seed 140 is disposed on the lower electrode 120. The filament seed 140 may induce formation of a filament serving as a current path in the resistive layer pattern 150. The filament seed 140 may include a carbon nano tube, a nano wire or a nano particle having a high conductivity. When voltages are applied to the resistive layer pattern 150 through the lower electrode 120 and the upper electrode 160, currents may selectively flow into the filament seed 140 due to the high conductivity of the carbon nano tube, the nano wire and/or the nano particle. The filament serving as the current path may be selectively formed on the filament seed 140 to define a uniform current path. Thus, formation of the filament may be efficiently adjusted to reduce reset currents and set currents and increase a response speed of the non-volatile semiconductor memory device 180. In example embodiments, the filament seed 140 may extend from the lower electrode 120 at a height which is substantially lower than a height of the resistive layer pattern 150.

The resistive layer pattern 150 is provided on the lower electrode 120 in the opening of the insulation layer pattern 130. The resistive layer pattern 150 may fill the opening in the insulation layer pattern 130 to cover the filament seed 140 on the lower electrode 120. In example embodiments, the resistive layer pattern 150 may be a single layer structure or a multi layer structure.

The resistive layer pattern 150 may include a metal oxide such as nickel oxide, niobium oxide, titanium oxide, zirconium oxide, hafnium oxide, cobalt oxide, iron oxide, aluminum oxide, chromium oxide, copper oxide, chalcogenide, lead titanium oxide (PTO), lead zirconate titanate (PZT), strontium bismuth tantalate (SBT), barium lanthanum titanate (BLT), barium strontium titanate (BST) and PCMO ((Pr, Ca)MnO₃). These may be used alone or in a combination of two or more thereof. In example embodiments, the resistive layer pattern 150 may be doped with impurities.

The upper electrode 160 is provided on the resistive layer pattern 150. The upper electrode 160 may include a metal or a metal nitride. In example embodiments, the upper electrode 160 may include tungsten, aluminum, titanium, hathium, iron, cobalt, zinc, manganese, molybdenum, niobium, copper or a nitride thereof. Alternatively, the upper electrode 160 may include iridium, rubidium, platinum, palladium, and so on. These may be used alone or in a combination of two or more thereof. For example, the upper electrode 160 may include iridium, rubidium, platinum, tungsten, aluminum, titanium nitride, and so on. In example embodiments, the upper electrode 160 may have a single layer structure or a multi layer structure.

In example embodiments, the non-volatile semiconductor memory device 180 may be a resistive random access memory (RRAM) device including the filament seed 140. Accordingly, when voltages are applied to the resistive layer pattern 150 through the lower electrode 120 and the upper electrode 160, the filament serving as the current path may be uniformly formed by the filament seed 140 in the resistive layer pattern 150 to reduce the reset and set currents.

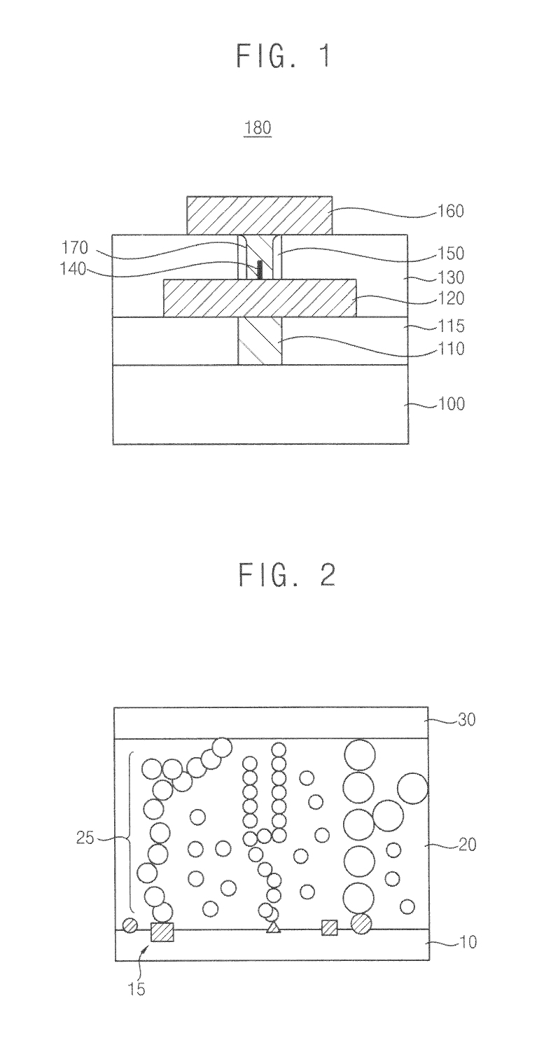

As illustrated in FIG. 2, when the RRAM device does not include the filament seed, filaments 25 serving as a current path may be randomly formed in a resistive layer pattern 20 to increase the reset currents and deteriorate a reliability of the RRAM device. A plurality of impurities and defects 15 caused by a dangling bond, a dislocation, a phase separation, and so on., may randomly exist on interfacial layers between the resistive layer pattern 20 and the lower and upper electrodes 10 and 30. This may be at least partly the result of the resistive layer pattern 20 and the lower and upper electrodes 10 and 30 including different materials. The impurities or the defects 15 randomly distributed over the interfacial layer between the resistive layer pattern 20 and the lower and upper electrodes 10 and 30 may induce formation of the filaments 25.

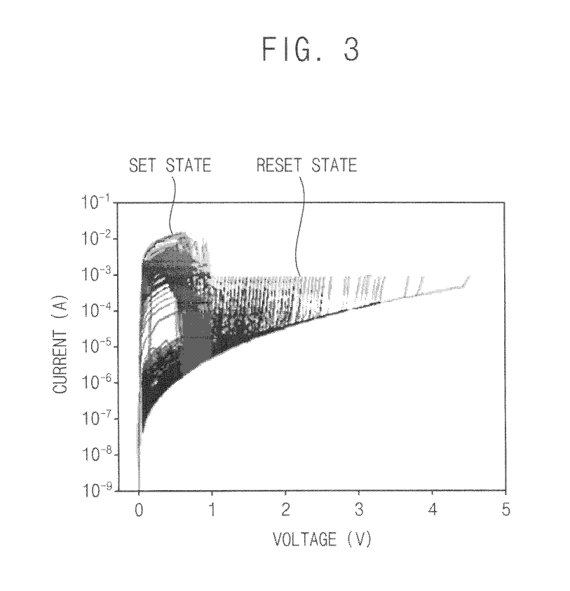

When voltages are applied to the lower and upper electrodes 10 and 30, the impurities or the defects 15, which are randomly distributed in the resistive layer pattern 20, may induce formation of the filament 25 serving as the current path in the resistive layer pattern 20 so that the filament 25 may be formed from the impurities or the defects 15. Thus, the filament 25 may be randomly formed in the resistive layer pattern 20. Furthermore, the reset and set currents may be increased according to an increasing number or size of the filaments 25. FIG. 3 is a graph illustrating a current value relative to applied voltages when the voltage is applied to a conventional non-volatile semiconductor memory device. As represented by this figure, a number and a size of the filaments 25 may not be efficiently adjusted so that the reset and set current may not be constant when the same voltage is applied to the resistive layer pattern 20.

According to example embodiments, the non-volatile semiconductor memory device 180 includes the filament seed 140 inducing the formation of a filament serving as the current path in the resistive layer pattern 150. As such, randomness in the formation of the filament in the resistive layer pattern 150 may be reduced, thereby enhancing efficiency and control of the conductivity of the resistive cell.

Hereinafter, a method of manufacturing a non-volatile semiconductor memory device in accordance with example embodiments will be explained in detail with reference to the accompanying drawings.

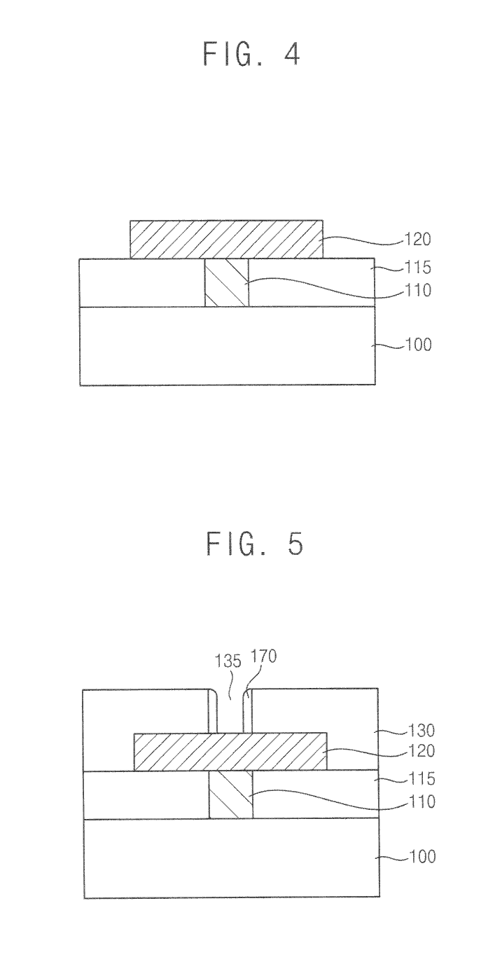

FIGS. 4 to 7 are cross-sectional views illustrating a method of manufacturing a non-volatile semiconductor memory device in accordance with example embodiments.

Referring to FIG. 4, a lower electrode 120 is formed on a substrate 100. The lower electrode 120 may be electrically connected to a switching element 110 on the substrate 100.

An insulating interlayer pattern 115 is formed on the substrate 100. The insulating interlayer pattern 115 may include an opening. The insulating interlayer pattern 115 may be formed using boro-phosphor silicate glass, phosphor silicate glass, undoped silicate glass, spin on glass, flowable oxide, tetraethylorthosilicate, plasma enhanced tetraethylorthosilicate, high density plasma chemical vapor deposition oxide by a chemical vapor deposition (CVD) process.

The switching element 110 is formed on the substrate 100. The switching element 110 is provided in the opening of the insulating interlayer pattern 115. In one example embodiment, the switching element 110 may be a transistor. In this case, after a gate electrode is formed on the substrate 100, source/drain regions (not illustrated) may be formed on the substrate 100. In another example embodiment, the switching element 110 may be a diode. Here, the diode may be a P—N junction diode including a first polysilicon layer pattern doped with p-type impurities and a second polysilicon layer pattern doped with n-type impurities.

A first conductive layer is formed on the switching element 110 and the insulating interlayer pattern 115. The first conductive layer may be formed using a metal or a metal compound having a high conductivity by a deposition process. In example embodiments, the first conductive layer may be formed using tungsten, aluminum, titanium, hafnium, iron, cobalt, zinc, manganese, molybdenum, niobium, copper or a nitride thereof. Alternatively, the first conductive layer may be formed using iridium, rubidium, platinum or palladium. These may be used alone or in a combination of two or more thereof. For example, the first conductive layer may be formed using tungsten, aluminum, titanium nitride, iridium, rubidium, platinum, and so on.

A hard mask (not illustrated) may be formed on the first conductive layer. In example embodiments, after the hard mask layer is formed using silicon nitride, the hard mask layer may be patterned to form the hard mask. The first conductive layer may be patterned using the hard mask as an etching mask by a dry etching process to form a lower electrode 120.

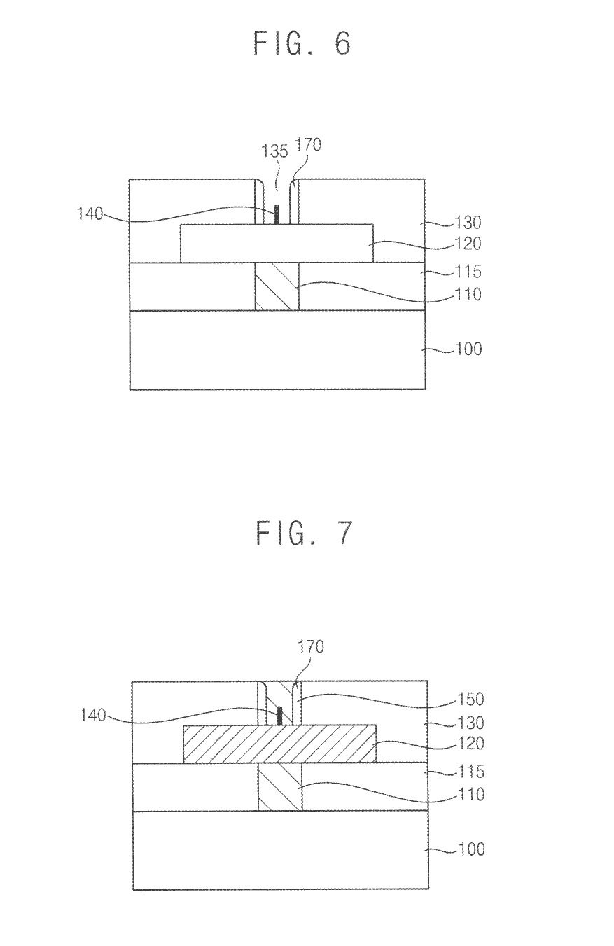

In example embodiments, a catalyst layer (not illustrated) may be formed on the lower electrode 120. The catalyst layer may be provided to induce a rapid growth of a filament seed 140 (see FIG. 6). The catalyst layer may include a transition metal or a noble metal (e.g., tungsten (W), nickel (Ni), iron (Fe), cobalt (Co), lead (Pb), platinum (Pt), gold (Au), and so on.). The catalyst layer may have a thickness of about several nanometers to about several tens of nanometers.

In one example embodiment, the lower electrode 120 may be formed and then the catalyst layer may be successively formed on the lower electrode 120. In another example embodiment, an insulation layer pattern 130 including an opening 135 (see FIG. 5) which exposes the lower electrode 120 may be formed and then the catalyst layer may be formed on the lower electrode 120.

Referring to FIG. 5, the insulation layer pattern 130 including the opening 135 is formed on the lower electrode 120 and the insulating interlayer pattern 115. The opening 135 may expose the lower electrode 120.

In formation of the insulation layer pattern 130, an insulation layer may be formed on the lower electrode 120 and the insulating interlayer pattern 115. In example embodiments, the insulation layer may be formed of silicon oxide by a CVD process. A mask may be formed on the insulation layer. The mask may expose a region on which the opening 135 is formed. The insulation layer may be dry-etched using the mask as the etching mask to form the insulation layer pattern 130 exposing the lower electrode 120.

In example embodiments, a spacer 170 may be formed on a sidewall of the opening 135 to reduce a width of the opening 135.

Referring to FIG. 6, the filament seed 140 is formed on the lower electrode 120 and in the opening 135. The filament seed 140 may induce a formation of a filament serving as a current path in a resistive layer pattern 150 (see FIG. 7) to reduce reset currents and set currents. The filament seed 140 may have a height substantially lower than that of the resistive layer pattern 150 from the lower electrode 120.

The filament seed 140 may be formed by a CVD process. For example, the filament seed 140 may be formed by an atmospheric CVD (AP-CVD) process, a plasma enhanced CVD (PE-CVD) process, a thermal CVD process, an electron cyclotron resonance CVD (ECR-CVD) process, an atomic layer deposition (ALD) process, a sputtering process, a nano printing process, and so on. A number or a size of the filament seed 140 may be appropriately adjusted according to process conditions for forming the filament seed 140. For example, a length of the filament seed 140 may be adjusted by controlling a process time in performing a chemical mechanical polishing (CMP) process.

In one example embodiment, the filament seed 140 may be formed from the lower electrode 120 by growing a carbon nanotube. In another example embodiment, the filament seed 140 may be formed from the lower electrode 120 by growing a nanowire. In still another example embodiment, the filament seed 140 may be formed from the lower electrode 120 by growing a nanoparticle.

When the filament seed 140 includes the carbon nanotube, the carbon nanotube may be formed by a CVD process at a temperature of about 400° C. to about 700° C. under a pressure of about 10 Torr to about 300 Torr in an atmosphere of hydrocarbon gas. While performing the CVD process using the hydrocarbon gas, the hydrocarbon gas may be thermally decomposed into carbon. Carbon formed by decomposing the hydrocarbon gas may be introduced into the opening 135 and may be adsorbed onto a surface of the lower electrode 120 to form the carbon nanotube on the lower electrode 120. The carbon nanotube may have a substantially lower height than the insulation layer pattern 130 from the lower electrode 120.

Referring to FIG. 7, the resistive layer pattern 150 is formed on the lower electrode 120 and in the opening 135 to cover the filament seed 140.

A resistive layer may be formed on the lower electrode 120 to fill the opening 135 in the insulation layer pattern 130. The resistive layer may be formed using a metal oxide. In example embodiments, the resistive layer may be formed using nickel oxide, niobium oxide, titanium oxide, zirconium oxide, hafnium oxide, cobalt oxide, iron oxide, aluminum oxide, chromium oxide, chalcogenide, copper oxide, lead titanium oxide, lead zirconate titanate, strontium bismuth tantalate, barium lanthanum titanate, barium strontium titanate PCMO ((Pr, Ca)MnO₃), and so on. These may be used alone or in a combination of two or more thereof. An etching process or a planarization process such as a CMP process may be performed on the resistive layer until the insulation layer pattern 130 is exposed. Accordingly, the resistive layer pattern 150 including the filament seed 140 is formed on the lower electrode 120.

A metal or a metal compound may be deposited on the resistive layer pattern 150 and the insulation layer pattern 130 to form a second conductive layer. In example embodiments, the second conductive layer may be formed using tungsten, aluminum, titanium, hafnium, iron, cobalt, zinc, manganese, molybdenum, niobium, copper or a nitride thereof. Alternatively, the second conductive layer may be formed using iridium, rubidium, platinum, palladium, and so on. These may be used alone or in a combination of two or more thereof. For example, the second conductive layer may be formed using iridium, rubidium, platinum, tungsten, aluminum titanium nitride, and so on.

The second conductive layer may be patterned to form an upper electrode on the insulation layer pattern 130 and the resistive layer pattern 150. Accordingly, the non-volatile semiconductor memory device 180 illustrated in FIG. 1 may be manufactured.

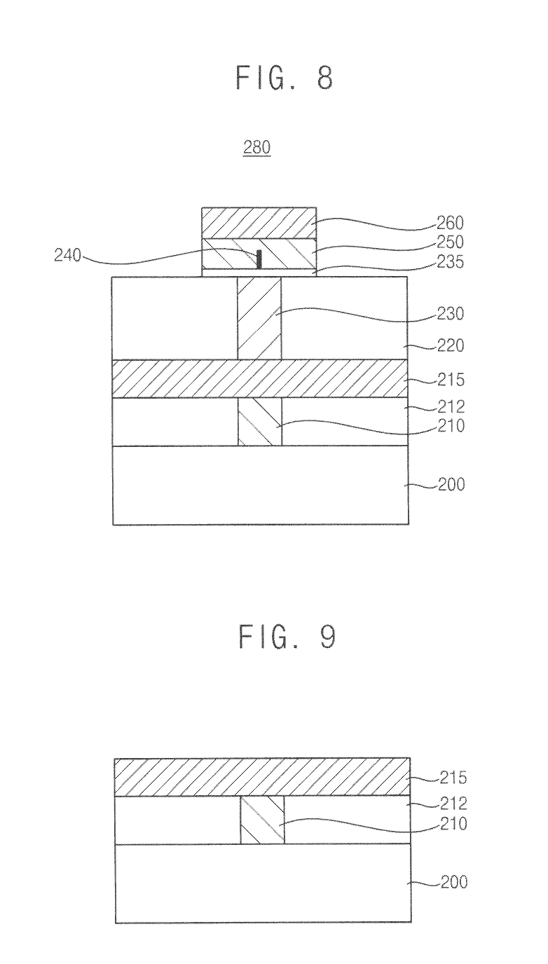

FIG. 8 is a cross-sectional view illustrating a non-volatile semiconductor memory device in accordance with example embodiments.

Referring to FIG. 8, the non-volatile semiconductor memory device 280 includes a substrate 200, a switching element 210, an insulating interlayer pattern 212, a wiring 215, an insulation layer pattern 220, a lower electrode 230, a catalyst layer pattern 235, a filament seed 240, a resistive layer pattern 250 and an upper electrode 260.

An insulating interlayer pattern 212 is formed on the substrate 200. The insulating interlayer pattern 212 may include an opening.

The switching element 210 is positioned in the opening of the insulating interlayer pattern 212. The switching element 210 may include a diode or a transistor such as a metal oxide semiconductor field effect transistor (MOSFET) formed on the substrate 200. In example embodiments, the diode may include a first polysilicon layer pattern doped with p-type impurities and a second polysilicon layer pattern doped with n-type impurities. Alternatively, the diode may include a Schottky diode having a polysilicon layer pattern doped with p-type impurities or a polysilicon layer pattern doped with n-type impurities.

The wiring 215 is provided on the insulating interlayer pattern 212 and the switching element 210. The wiring 215 may be electrically connected to the switching element 210 formed on the substrate 200. In example embodiments, the wiring 215 may include a conductive wiring such as a contact plug, a bit line, and so on. The wiring 215 may include a metal, a metal compound, or other conductive material. In example embodiments, the wiring 215 may include tungsten, aluminum, titanium, hafnium, iron, cobalt, zinc, manganese, molybdenum, niobium, copper or a nitride thereof. These may be used alone or in a combination of two or more thereof.

The insulation layer pattern 220 is disposed on the wiring 215 and has an opening exposing the wiring 215. The insulation layer pattern 220 may include silicon oxide. The opening in the insulation layer pattern 220 may define a region on which the lower electrode 230 is formed. In example embodiments, a spacer (not illustrated) may be formed on a sidewall of the opening.

The lower electrode 230 is provided on the opening in the insulation layer pattern 220. The lower electrode 230 may be electrically connected to the wiring 215. The lower electrode 230 may include a metal or a metal compound having a high conductivity. The metal or the metal compound included in the lower electrode 230 may be substantially the same as those of the lower electrode 120 previously described in connection with FIG. 1.

The catalyst layer pattern 235 is formed on the lower electrode 230 and the insulation layer pattern 220. The catalyst layer pattern 235 may serve as accelerating a growth of the filament seed 240. The materials included in the catalyst layer pattern 235 and the thickness of the catalyst layer pattern 235 may be substantially the same as those of the catalyst layer previously described in connection with FIG. 1.

The filament seed 240 is disposed on the catalyst layer pattern 235. The filament seed 240 may induce a formation of a filament serving as a current path in the resistive layer pattern 250 to reduce reset currents and set currents. The filament seed 240 may include a carbon nano tube, a nanowire, a nanoparticle, and so on, having a high conductivity and may be formed from the catalyst layer pattern 235.

The resistive layer pattern 250 is provided on the catalyst layer pattern 235 on which the filament seed 240 is formed to cover the filament seed 240. The resistive layer pattern 250 may be provided between the catalyst layer pattern 235 and the upper electrode 260. The resistive layer pattern 250 may include a metal oxide. The materials included in the resistive layer pattern 250 may be substantially the same as those of the resistive layer pattern 150 described previously in connection with FIG. 1. In example embodiments, the resistive layer pattern 250 may be a single layer structure or a multi layer structure.

The upper electrode 260 is provided on the resistive layer pattern 250. The upper electrode 260 may include a metal or a metal nitride. For example, the upper electrode 260 may include iridium, rubidium, platinum, tungsten, aluminum or titanium nitride.

According to example embodiments, the non-volatile semiconductor memory device 280 includes a filament seed 240 inducing the formation of the filament serving as the current path in the resistive layer pattern 250. Thus, formation of the filament serving as the current path in the resistive layer pattern 250 may be efficiently controlled to reduce the reset and set currents.

Hereinafter, a method of manufacturing a non-volatile semiconductor memory device in accordance with example embodiments will be explained in detail with reference to the accompanying drawings.

FIGS. 9 to 12 are cross sectional views illustrating a method of manufacturing a non-volatile semiconductor memory device in accordance with example embodiments

Referring to FIG. 9, an insulating interlayer pattern 212 is formed on the substrate 200. The insulating interlayer pattern 212 may include an opening. The insulating interlayer pattern 212 may be formed using boro-phosphor silicate glass, phosphor silicate glass, undoped silicate glass, spin on glass, flowable oxide, tetraethylorthosilicate, plasma enhanced tetraethylorthosilicate, high density plasma chemical vapor deposition oxide by a CVD process.

The switching element 210 is formed on the substrate 200. The switching element 210 is provided in the opening of the insulating interlayer pattern 212. In example embodiments, the switching element 210 may include a transistor or a diode.

The wiring 215 is formed on the switching element 210 and the insulating interlayer pattern 212. The wiring 215 may be electrically connected to the switching element 210 on the substrate 200. The wiring 215 may be formed using a metal or a metal compound by a deposition process.

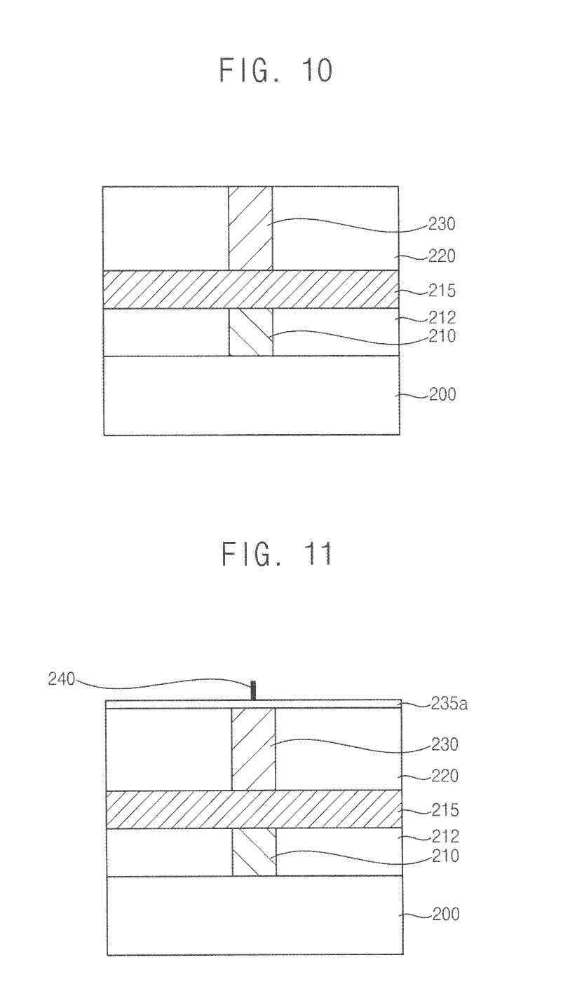

Referring to FIG. 10, an insulation layer pattern 220 including an opening and the lower electrode 230 are formed on the wiring 215.

In formation of the insulation layer pattern 220, an insulation layer may be formed on the wiring 215. The insulation layer may be formed of silicon oxide. A mask may be formed on the insulation layer. The mask may expose a region on which the opening is formed. The insulation layer may be etched using the mask to form opening in the insulation layer pattern 230 exposing the wiring 215.

A first conductive layer is formed on the insulation layer pattern 230 to fill the opening in the insulation layer pattern 230. The first conductive layer may be formed using a metal or a metal compound having a high conductivity. In example embodiments, the first conductive layer may be formed using tungsten, aluminum, titanium, hafnium, iron, cobalt, zinc, manganese, molybdenum, niobium, copper or a nitride thereof. Alternatively, the first conductive layer may be formed using iridium, rubidium, platinum, palladium, and so on. These may be used alone or in a combination of two or more thereof. For example, the first conductive layer may be formed using iridium, rubidium, platinum, tungsten, aluminum, titanium nitride, and so on.

The first conductive layer may be planarized by a CMP process until the insulation layer pattern 230 is exposed to form the lower electrode 230 filling the opening.

Referring to FIG. 11, a catalyst layer 235a and a filament seed 240 are formed on the lower electrode 230 and the insulation layer pattern 220.

The catalyst layer 235a may be provided to induce a rapid growth of the filament seed 240. The catalyst layer 235a may include a metal layer or a porous active layer. In example embodiments, the metal layer may be formed using a transition metal or a noble metal such as tungsten, nickel, iron, cobalt, lead, platinum, gold, and so on. The catalyst layer 235a may have a thickness of about several nanometers to about several tens of nanometers.

The filament seed 240 is formed on the catalyst layer 235a. The filament seed 240 may induce a formation of the filament serving as a current path in a resistive layer pattern to reduce reset currents and set currents. The filament seed 240 may be formed on a predetermined portion of a surface of the catalyst layer 235a corresponding to the lower electrode 230.

In one example embodiment, the filament seed 240 may be formed from the surface of the catalyst layer 235a by growing a carbon nanotube. In another example embodiment, the filament seed 240 may be formed from the surface of the catalyst layer 235a by growing a nanowire. In still another example embodiment, the filament seed 240 may be formed from the surface of the catalyst layer 235a by growing a nanoparticle.

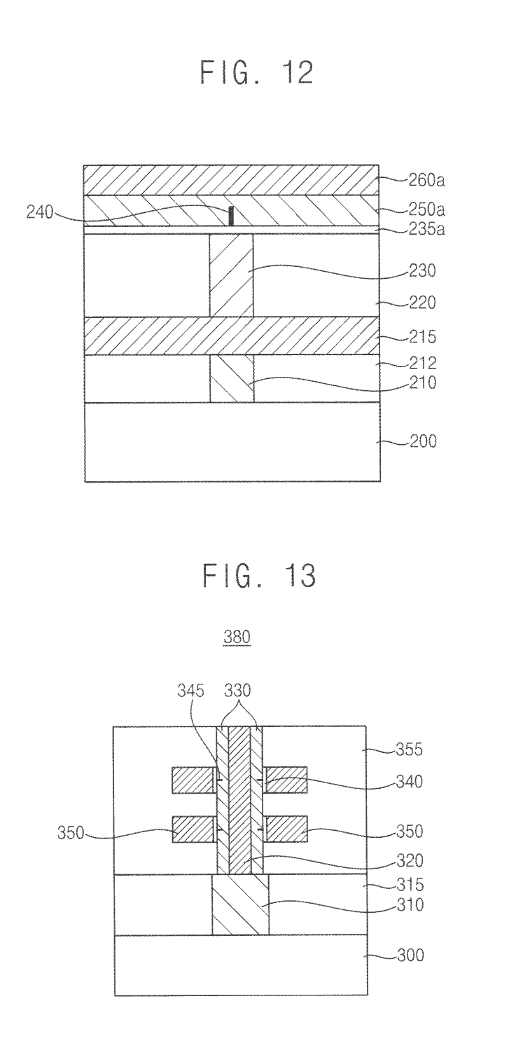

Referring to FIG. 12, a resistive layer 250a and a second conductive layer 260a are formed on the catalyst layer 235a to cover the filament seed 240.

The resistive layer 250a may be formed using a metal oxide. In example embodiments, the resistive layer 250a may be formed using nickel oxide, niobium oxide, titanium oxide, zirconium oxide, hafnium oxide, cobalt oxide, iron oxide, aluminum oxide, chromium oxide, chalcogenide, copper oxide, lead titanium oxide, lead zirconate titanate, strontium bismuth tantalate, barium lanthanum titanate, barium strontium titanate, PCMO ((Pr, Ca)MnO₃), and so on. These may be used alone or in a combination of two or more thereof.

The second conductive layer 260a is formed on the resistive layer 250a. The second conductive layer 260a may be formed using materials substantially the same as those of the first conductive layer for forming the lower electrode 230. For example, the second conductive layer 260a may be formed using iridium, rubidium, platinum, tungsten, aluminum titanium nitride, and so on.

A hard mask is formed on the second conductive layer 260a. The hard mask may define a region on which an upper electrode is formed. The second conductive layer 260a, the resistive layer 250a and the catalyst layer 235a may be patterned using the hard mask as an etching mask. In example embodiments, the second conductive layer 260a, the resistive layer 250a and the catalyst layer 235a may be dry-etched until the insulation layer pattern 220 is exposed. Accordingly, the non-volatile memory device illustrated in FIG. 7 may be manufactured.

FIG. 13 is a cross sectional view illustrating a non-volatile semiconductor memory device in accordance with example embodiments.

Referring to FIG. 13, the non-volatile semiconductor memory device 380 includes a substrate 300, an insulating interlayer pattern 315, a switching element 310, a first electrode 320, a resistive layer pattern 330, a second electrode 350, a catalyst layer pattern 340, a filament seed 345 and an insulation layer pattern 355.

An insulating interlayer pattern 315 is formed on the substrate 300. The insulating interlayer pattern 315 includes an opening.

The switching element 310 is positioned in the opening of the insulating interlayer pattern 315. The switching element 310 may include a diode or a transistor such as a metal oxide semiconductor field effect transistor (MOSFET) formed on the substrate 300. In example embodiments, the diode may include a first polysilicon layer pattern doped with p-type impurities and a second polysilicon layer pattern doped with n-type impurities. Alternatively, the diode may include a Schottky diode having a polysilicon layer pattern doped with p-type impurities or a polysilicon layer pattern doped with n-type impurities.

The first electrode 320 is provided on the switching element 310. The first electrode 320 may be electrically connected to the switching element 310. In example embodiments, the first electrode 320 may have a bar shape substantially perpendicular to a surface of the substrate 300. The first electrode 320 may include tungsten, aluminum, titanium, hafnium, iron, cobalt, zinc, manganese, molybdenum, niobium, copper or a nitride thereof. Alternatively, first electrode 320 may include iridium, rubidium, platinum, palladium, and so on. These may be used alone or in a combination of two or more thereof. For example, the first electrode 320 may include tungsten, aluminum, titanium, hafnium, iron, cobalt, zinc, manganese, molybdenum, niobium, copper or a nitride thereof.

The resistive layer pattern 330 is provided between the first electrode 320 and the second electrode 350. The resistive layer pattern 330 may partially or completely surround the first electrode 320 and may also cover the filament seed 345 on the catalyst layer 340. The resistive layer pattern 330 may include a metal oxide. The materials included in the resistive layer pattern 330 may be substantially the same as those of the resistive layer pattern 150 described in connection FIG. 1. In example embodiments, the resistive layer pattern 330 may be a single layer structure or a multi layer structure.

The second electrode 350 is provided on an outer sidewall of the resistive layer pattern 330. A plurality of second electrodes 350 may correspond to one another with respect to the first electrode 320. In example embodiments, a pair of second electrodes 350 may be provided opposite to one another on the outer sidewall of the first electrode 320. When a pair of second electrodes 350 is provided, each of the second electrodes 320 may be contacted with the catalyst layer pattern 340 and may be also electrically insulated from each other by the insulation layer pattern 355.

In example embodiments, the second electrode 350 may include a metal or a metal compound having a high conductivity. For example, the second electrode 350 may be formed using materials substantially the same as those of the first electrode 320.

The catalyst layer pattern 340 may be formed between the second electrode 350 and the resistive layer pattern 345. The catalyst layer pattern 340 may serve as accelerating a growth of the filament seed 345. The materials included in the catalyst layer pattern 340 and the thickness of the catalyst layer pattern 340 may be substantially the same as those of the catalyst layer described in connection with FIG. 1.

The filament seed 345 may be disposed on the catalyst layer pattern 340 and may be embedded in the resistive layer pattern 330. The filament seed 345 may induce formation of a filament serving as a current path. That is, the filament seed 345 may make the current path in the resistive layer pattern 330 more uniform to reduce reset currents and set currents. The filament seed 345 may include a carbon nano tube, a nanowire, a nanoparticle, and so on. having a high conductivity and may be grown from the catalyst layer pattern 340.

The insulation layer pattern 355 encloses the resistive layer pattern 330 and the second electrode 350. The insulation layer pattern 355 may electrically insulate the second electrode 350 from an adjacent second electrode 350. In example embodiments, the insulation layer pattern 355 may be formed using silicon oxide. In example embodiments, the insulation layer pattern 355 may have a single layer structure or a multi layer structure.

In example embodiments, the non-volatile semiconductor memory device 380 may be a RRAM device having a vertically stacked structure.

FIG. 14 is a block diagram illustrating another example embodiment. Referring to FIG. 14, a memory 410 is connected to a memory controller 420. The memory 410 may be a RRAM device having a unit cell that includes a filament seed including a carbon nanotube, a nanowire, a nanoparticle, and so on, as described above in connection with FIGS. 1 to 12.

The memory controller 420 may provide input signal to control operations of the memory 410. For example, a memory controller of a memory card may transfer a command of a host to control input/output data and control various data of a memory based on an applied control signal. The memory 410 and the memory controller 420 may be applied to not only the memory card but also digital products including a memory.

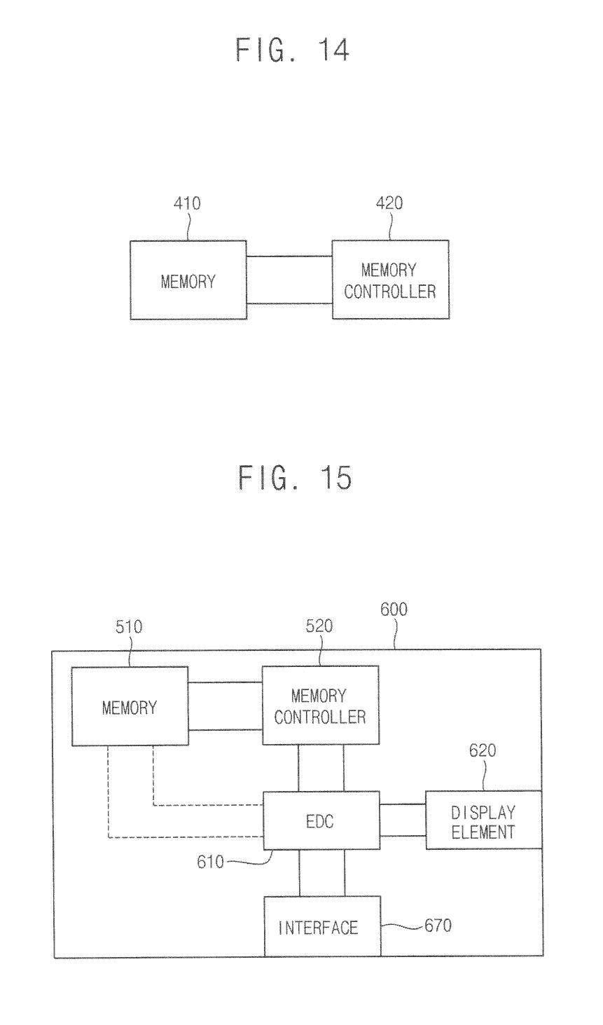

FIG. 15 is a block diagram illustrating another example embodiment.

Referring to FIG. 15, this example embodiment represents a portable device 600.

Examples of the portable device 600 may include a MP3 player, an audio player, a video player, a portable-multi-media player which are capable of playing audio and video, and so on. The portable device 600 may include a memory 510, a memory controller 520, an encoder and decoder (EDC) 610, presentation components 620 and interface 630. The memory 510 may be a RRAM device having a unit cell that includes a filament seed including a carbon nanotube, a nanowire, a nanoparticle, and so on, as described previously in connection with FIGS. 1 to 12.

Data is input to and output from the memory 510 via the memory controller 520 by an encoder and decoder (EDC) 610. The data may be directly input to the memory 510 from the EDC 610 and/or directly output from the memory 510 to the EDC 610.

The EDC 610 encodes data for storage in the memory 510. For example, the EDC 610 may perform MP3 encoding on audio data for storage in the memory 510. Alternatively, the EDC 610 may perform MPEG encoding (e.g., MPEG2, MPEG4, and so on.) on video data for storage in the memory 510.

Still further, the EDC 610 may include multiple encoders for encoding different types of data according to different data formats. For example, the EDC 610 may include an MP3 encoder for audio data and an MPEG encoder for video data.

The EDC 610 may decode output from the memory 510. For example, the EDC 610 may perform MP3 decoding on audio data output from the memory 510. Alternatively, the EDC 610 may perform MPEG decoding (e.g., MPEG2, MPEG4, and so on.) on video data output from the memory 510. Still further, the EDC 610 may include multiple decoders for decoding different types of data according to different data formats. For example, the EDC 610 may include an MP3 decoder for audio data and an MPEG decoder for video data.

It will also be appreciated that EDC 610 may include only decoders. For example, already encoded data may be received by the EDC 610 and passed to the memory controller 520 and/or the memory 510.

The EDC 610 may receive data for encoding, or receive already encoded data, via the interface 630. The interface 630 may conform to a known standard (e.g., firewire, USB, and so on.). The interface 630 may also include more than one interface. For example, interface 630 may include a firewire interface, a USB interface, and so on. Data from the memory 510 may also be output via the interface 630.

The presentation components 620 may present data output from the memory, and/or decoded by the EDC 610, to a user. For example, the presentation components 620 may include a speaker jack for outputting audio data, a display screen for outputting video data, and so on.

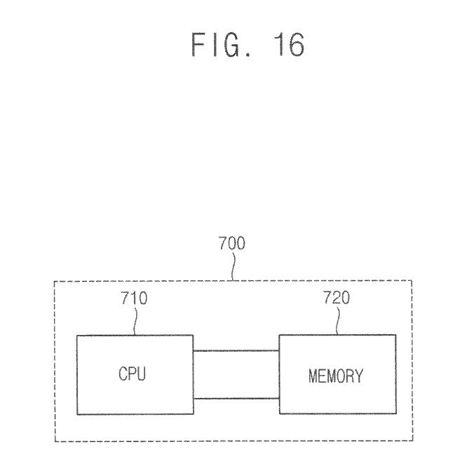

FIG. 16 is a block diagram illustrating another example embodiment.

Referring to FIG. 16, a memory 720 is connected to a central processing unit (CPU) 710 within a computer system 700. The memory 720 may be a RRAM device having a unit cell that includes a filament seed including a carbon nanotube, a nanowire, a nanoparticle, and so on, as described above in connection with FIGS. 1 to 12.

As one example, the computer system 700 may be laptop computer using the RRAM device as a main storage medium. As another example, the computer system 700 may be digital products including the memory 720 which capable of storing data and controlling function of the digital products. The memory 720 may be directly connected with the CPU 710, connected via bus, and so on.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A non-volatile semiconductor memory device, comprising:
a lower electrode;
an upper electrode;
a resistive layer pattern located between the lower electrode and the upper electrode; and
a filament seed embedded in the resistive layer pattern, the filament seed including at least one of a carbon nanotube, a nanowire and a nanoparticle.

2. The non-volatile semiconductor memory device of claim 1, wherein the filament seed is a growth from a surface of the lower electrode.

3. The non-volatile semiconductor memory device of claim 1, further comprising a catalyst layer formed on the lower electrode.

4. The non-volatile semiconductor memory device of claim 3, wherein the catalyst layer includes at least one selected from the group consisting of cobalt, nickel, iron, tungsten, titanium, platinum, iridium, rubidium, gold, tungsten silicide, cobalt silicide, nickel silicide, titanium silicide and titanium tungsten.

5. The non-volatile semiconductor memory device of claim 3, wherein the filament seed is a growth from a surface of the catalyst layer.

6. The non-volatile semiconductor memory device of claim 1, wherein the resistive layer pattern includes at least one selected from the group consisting of niobium oxide, titanium oxide, hafnium oxide, cobalt oxide, iron oxide, copper oxide, aluminum oxide, chromium oxide, chalcogenide, lead titanium oxide (PTO), lead zirconate titanate (PZT), strontium bismuth tantalate (SBT), barium lanthanum titanate (BLT), barium strontium titanate (BLT) and PCMO ((Pr, Ca)MnO3).

7. The non-volatile semiconductor memory device of claim 1, further comprising a switching element electrically connected to the lower electrode, the switching element including at least one of a transistor and a diode.

8. The non-volatile semiconductor memory device of claim 1, further comprising an insulation layer pattern including an opening

9. The non-volatile semiconductor memory device of claim 8, wherein the opening is filled with the resistive layer pattern.

10. The non-volatile semiconductor memory device of claim 8, wherein the opening is filled with the lower electrode.

11. The non-volatile semiconductor memory device of claim 8, further comprising a spacer on a sidewall of the opening

12. The non-volatile semiconductor memory device of claim 1, wherein a height of the filament seed is less than a height of the resistive layer pattern.

13-20. (canceled)
